(19) United States
(12) Patent Application Publication
(10) Pub. No.: US 2025/0388456 A1
(43) Pub. Date: Dec. 25, 2025

(54) MICROMECHANICAL PRESSURE SENSOR HAVING AT LEAST TWO MEMBRANES FOR DETERMINING A PRESSURE VALUE, AND CORRESPONDING METHOD

(71) Applicant: Robert Bosch GmbH, Stuttgart (DE)

(72) Inventors: Heribert Weber, Nuertingen (DE); Johannes Classen, Reutlingen (DE); Volkmar Senz, Metzingen (DE); Andreas Scheurle, Leonberg (DE)

(21) Appl. No.: 18/878,501

(22) PCT Filed: May 17, 2023
(86) PCT No.: PCT/EP2023/063344

§ 371 Date: Feb. 13, 2025

(30) Foreign Application Priority Data
Jul. 7, 2022 (DE) 10 2022 206 969.2

(51) Int. Cl. B81B 3/00; G01L 9/00; G01L 15/00

(52) U.S. Cl. CPC B81B 3/0051; G01L 9/0052; G01L 9/0072; G01L 15/00; B81B 2201/0264; B81B 2203/0127; B81B 2203/0315; B81B 2203/0338; B81B 2207/07

(57) ABSTRACT

A micromechanical pressure sensor. The sensor has at least one membrane of a first membrane type, using which a first pressure sensor variable in a first pressure range can be detected. To enable the bending of the membrane, the first membrane is formed above a first cavern in/on a substrate including semiconducting material. In/on this substrate, at least one second membrane of a second membrane type is formed above a second cavern, using which a second pressure sensor variable in a second pressure range can be detected. A bending behavior of each of the membranes generate pressure sensor variables that are ascertained within different pressure ranges. The different pressure ranges can partially overlap. The different bending behavior of the membranes of the different membrane types is caused by a different design of the geometric expansions of the first and second membrane in at least one lateral direction.

### FIELD

The present invention relates to a micromechanical pressure sensor having at least two membranes for determining a pressure value, and to a corresponding operating method.

### BACKGROUND INFORMATION

Typical micromechanical pressure sensors have a membrane in which a pressure value of an adjacent medium is detected depending on the bending of the membrane. The membrane is usually designed for a pressure range in which it can be bent in a defined manner. If this pressure range is exceeded, stop elements can be provided below the membrane or on the cavern floor that stop/limit the bending and thus the membrane movement. Alternatively, the membrane can also rest on the cavern floor when the specified pressure range is exceeded, so that further bending of the membrane is prevented. Such a pressure sensor system is described for example in Germany Patent Application No. DE 10 2009 001 924 A1. In this case, an insulating layer can be provided on the cavern floor and/or on the underside of the membrane in order to electrically separate the movable upper electrode in the membrane from the static/stationary lower electrode on the cavern floor in a pressure sensor with capacitive measurement value detection.

To detect different pressure ranges, different membranes with different bending behavior can be integrated on a substrate. Corresponding pressure sensors are described in German Patent Application No. DE 101 32 269 A1 and PCT Patent Application No. WO 00/37913 A1.

### SUMMARY

The present invention provides a micromechanical pressure sensor in which a pressure value/pressure curve is determined on the basis of sensor variables of two membranes that cover different pressure ranges. Furthermore, a method for determining the pressure value of such a micromechanical pressure sensor is provided according to the present invention.

The micromechanical pressure sensor according to an example embodiment of the present invention has at least one membrane of a first membrane type, by means of which a first pressure sensor variable in a first pressure range can be detected. In order to enable the bending of the membrane, the first membrane is formed above a first cavern in a substrate consisting in particular of semiconducting material and/or in a layer system additionally provided on the substrate. In/on the substrate and/or in/on the layer system additionally provided on the substrate, at least one second membrane of a second membrane type is formed above a second cavern, by means of which a second pressure sensor variable in a second pressure range can be detected. The two membrane types are designed in such a way that their bending behavior generates pressure sensor variables of which the derived pressure values lie within different pressure ranges. It is intended that these pressure ranges partially overlap or that the first pressure range lies substantially within the further, second pressure range. A main feature of the present invention is that the different bending behavior of the membrane types is caused by a different design of the extensions of the first and second membrane types in at least one lateral direction. Furthermore, at least one cavern of the first membrane type and one cavern of the second membrane type are connected to one another by means of a pressure equalization channel.

The use of two membranes may have the advantage that the pressure value detected by the pressure sensor can be detected much more accurately within the two pressure ranges. Since non-linear dependencies can occur when a membrane bends at the upper limit of its maximum specified pressure range, it may specifically be intended that by providing at least two membrane types/designs and corresponding processing of the pressure sensor variables in each case over a large pressure range, a largely and at least partially linear derivation of the pressure value can be achieved. Nonlinear dependencies can be further avoided by providing a corresponding number of different membrane types for a desired pressure range and stopping/limiting their membrane deflections correspondingly early.

In one example embodiment of the present invention, the first and second membrane types differ substantially in the lateral extensions of the corresponding membranes. They may differ in only one of the two lateral directions, such that, for example, both membranes have the same length but different widths. The lateral extension of the membrane may differ in at least one (surface) direction, for example by a factor of two, three, or four. This means, for example, that a membrane of the first membrane type has twice, three times, or four times the width or in general a correspondingly multiplied edge length compared to a membrane of the second membrane type. Alternatively, one membrane may be longer and/or wider than the other membrane by one-half, one-third, one-quarter, etc.

In general, the membranes used can have any geometric flat shape. When using round membranes, the two membrane types differ in their radii. In the case of ellipsoidal membranes, only one of the radii may vary between the two membrane types. For rectangular membranes, both the length and width can be varied. The variation of both the length and width of a rectangular membrane can also lead to different sensitivities in pressure detection, since a larger area leads to a larger maximum deflection of the membrane for the same applied pressure and otherwise the same structure of the membrane. Furthermore, by varying the at least one lateral extension of the two-dimensional membranes on or in the substrate and/or on or in the layer system additionally provided on the substrate, the desired pressure ranges to be detected can be specifically set. In addition, the deflection of the membrane in each case can be stopped/limited by stop structures.

The caverns located below the membranes are connected at least to one neighboring cavern via at least one pressure equalization channel. In particular, at least one first cavern of a first membrane type is connected directly or indirectly to at least one second cavern of a second membrane type. Such a connection makes it possible to include an identical cavern internal pressure in all interconnected caverns when producing the sensors, so that the same initial conditions prevail when detecting the pressure sensor variables with regard to the influence of the cavern internal pressure on the pressure sensor variable in each case. The larger total volume of all connected caverns can also lessen an outgassing effect that occurs during manufacture and/or when the system heats up during operation and that influences the detected pressure sensor variables. The particles entering the (total) cavern volume due to the outgassing effect are thus distributed over a larger volume, resulting in a stabilization of the sensor signal and in particular of the offset depending on the temperature.

Furthermore, according to an example embodiment of the present invention, each membrane has its own membrane enclosure region, through which the movement of the membrane can take place independently of other membranes. The membrane enclosure region can further be arranged between two membranes in such a way that it can be used for both one membrane and the other membrane. The membrane enclosure region can also have elements as a separating structure both for the movement of the membrane and for the cavern.

In order to detect the pressure value on the basis of the bending of the membranes, two membranes of the first membrane type and one membrane of the second membrane type can be provided on the substrate in order to detect the underlying pressure sensor variable. By detecting the bending of two membranes of the first membrane type, the pressure sensor variable in the first pressure range can be detected more accurately. This can be the case, for example, if the membranes of the first membrane type are designed for a lower pressure range and the membrane of the second membrane type is designed for a higher pressure range. In order to be able to achieve a high measurement sensitivity in a low pressure range, the membranes of the first membrane type are designed to have a larger surface area than the membrane of the second membrane type, whereby even small applied pressure changes lead to larger deflections of the membranes of the first membrane type. These larger deflections for small pressure changes lead to a larger (value) change in the detected pressure sensor variable or the pressure value derived therefrom in a low pressure range in relation to the lower applied pressure values than would be the case with smaller membrane areas (of the second membrane type). In one embodiment, the two pressure sensor variables of the first membrane type can be detected and averaged separately. In a further embodiment, the detection means for detecting the pressure sensor variables of the first membrane type can be electrically connected in such a way that they form a half-bridge arrangement or a full-bridge arrangement of a Wheatstone bridge configuration. In contrast, the detection means for detecting the pressure sensor variables of the second membrane type can only be arranged in a Wheatstone half-bridge or a quarter-bridge configuration for detecting a pressure value. If the deflection of a membrane leads for example to a change in a differential capacitor arrangement, this can already be used to set up a Wheatstone half-bridge arrangement to determine a pressure value. If the deflection of a membrane leads for example to a change in a simple capacitor structure, the measurement signals/measurement variables from two membranes of one membrane type must be connected to form a Wheatstone half-bridge arrangement, or only a quarter-bridge configuration can be implemented. Based on how many pressure sensor variables are generated/ascertained during the deflection of a membrane of a membrane type, any other electrical connections in a Wheatstone bridge arrangement are possible. Furthermore, the pressure sensor variables of a first membrane type can be connected to the pressure sensor variables of a second membrane type to form a Wheatstone half or full bridge. The interconnection of pressure sensor variables in a Wheatstone bridge arrangement allows a more accurate determination of a pressure value at least in a first pressure range of a first membrane type and/or at least in a second pressure range of a second membrane type.

In general, the pressure sensor may have a multiple of membranes of the first membrane type compared to membranes of the second membrane type. For example, in addition to the doubling already mentioned above, a tripling or quadrupling may also be planned.

According to an example embodiment of the present invention, in order to effectively utilize the area on the substrate, the membranes of the first membrane type and the membranes of the second membrane type can be arranged accordingly. A symmetrical arrangement of the first and second membrane types is recommended, in particular if there is a plurality of membranes of at least one type and in particular in a Wheatstone bridge arrangement, since otherwise offsets in the signal may occur.

Alternatively, according to an example embodiment of the present invention, two different membrane types can be arranged symmetrically to each other and/or at least two membranes of a second membrane type can be arranged symmetrically to a central perpendicular or a mirror axis of at least one first membrane of a first membrane type.

The variation in extension can also play a role in the arrangement. For example, two membranes of the first membrane type which have twice the width of the membrane of the second type can be arranged next to one another and can be arranged with their width and/or length adjacent to a membrane enclosure region of at least one membrane of the second membrane type and/or can have, with their width and/or length, a common membrane enclosure region with at least one membrane of the second membrane type.

For example, two membranes of the second membrane type, the width of which corresponds to only half the width of a membrane of the first membrane type, can also be provided between two membranes of the first membrane type and can optionally have at least one common membrane enclosure region with a membrane of the first membrane type.

In addition, according to an example embodiment of the present invention, the pressure equalization channels can also be arranged symmetrically, i.e., centrally relative to one of the cavern sides. Such a design enables faster pressure equalization between the caverns.

In a particular example embodiment of the present invention, the first membrane type is provided for detecting a lower (average) pressure range, in particular due to its larger membrane area, while the second membrane type, in particular due to its smaller membrane area, is provided for a higher (average) pressure range.

The membranes of at least one membrane type may also have stiffeners or additional thickenings. These stiffeners or thickenings can also influence the pressure range, so that a targeted adjustment of the desired pressure range is possible in this way. In addition, stop elements can be provided on the underside of the membrane or on the cavern floor that stop/limit a movement of the membrane, for example to prevent the membrane and/or at least one electrode attached thereto from resting directly on the cavern floor and/or an electrode provided thereon. These stop elements can also ensure that the membrane is adequately supported and does not break when the pressure exceeds the specification limit. In addition, insulating layers can be provided on the underside of the membrane and/or on the cavern floor. Furthermore, insulating layers can also be provided on surfaces of electrodes which are attached to the membrane and/or to the cavern floor in order to be able to avoid a short circuit between the electrodes when they come into contact.

In general, all conventional detection arrangements can be used to detect the pressure sensor variables of the first and second membrane types. It is thus possible to detect the movement of the membranes by means of a capacitive design in which the membrane has or controls at least one first movable electrode or the membrane itself is designed as a first movable electrode and at least one stationary second electrode is provided on the floor of the cavern. In this case, the membrane underside adjacent to the cavern region, at least the underside of an electrode attached to the membrane underside, the cavern floor opposite the membrane underside and/or the top side of at least one second stationary electrode provided on the cavern floor within the cavern region may have an insulating layer, so that when the membrane and/or the movable electrode attached to the membrane is placed on the cavern floor and/or on the at least one stationary second electrode on the cavern floor, no electrical short circuit is produced. It is also possible to use piezoresistive elements on or in the membrane to detect its bending.

Further advantages can be seen from the following description of exemplary embodiments of the present invention.

### BRIEF DESCRIPTION OF THE DRAWINGS

FIG. 1 shows an example embodiment of the present invention with two membranes of each of the two membrane types.

FIG. 2 shows the symmetrical arrangement of one membrane each of the two membrane types, according to an example embodiment of the present invention.

FIG. 3 shows an example embodiment of the present invention in which a common membrane clamping region is used.

FIG. 4 shows a possibility for arranging a plurality of membranes on the substrate surface in a manner that optimizes the area, according to an example embodiment of the present invention.

FIG. 5 shows a block diagram of the evaluation of the detected pressure sensor variables of the pressure sensor, according to an example embodiment of the present invention.

### DETAILED DESCRIPTION OF EXAMPLE EMBODIMENTS

The present invention provides a micromechanical pressure sensor which can detect at least two pressure ranges of different sizes by means of at least two different membrane types on a common substrate. In addition, the design of the membranes with respect to the different pressure ranges allows a greater accuracy of the detected sensor variable or pressure value to be achieved than would be possible with only one membrane. The two measured pressure ranges can merge into one another and thus the pressure of a medium applied to the membranes can be continuously detected. Alternatively, the two pressure ranges may not overlap. In general, when using different membranes, use can be made of the fact that larger membrane surfaces can be bent/deflected more when low pressure is applied than smaller membrane surfaces. By providing at least two membrane surfaces of different sizes, pressure sensor variables in different pressure ranges can advantageously be detected particularly accurately/precisely.

The main feature of the present invention includes selecting at least the lateral extensions of the membrane surfaces for both membrane types in such a way that at least one of the lateral extensions is varied in the first membrane type compared to the second membrane type in order to enable scaling of the membrane surface and the pressure ranges to be covered by the membranes. The sensitivities, the design of the membrane surfaces, and/or the permissible deflection ranges of both membranes can be designed such that the linear dependence of the bending of the membrane on the pressure of the detected pressure sensor variable of the second membrane of the second membrane type continues to exist at a pressure value at which the first membrane of the first membrane type departs from its linear dependence on the applied pressure, decreases it, or comes to a stop. Thus, with the two membrane types, two at least partially overlapping and complementary pressure ranges can be measured and covered.

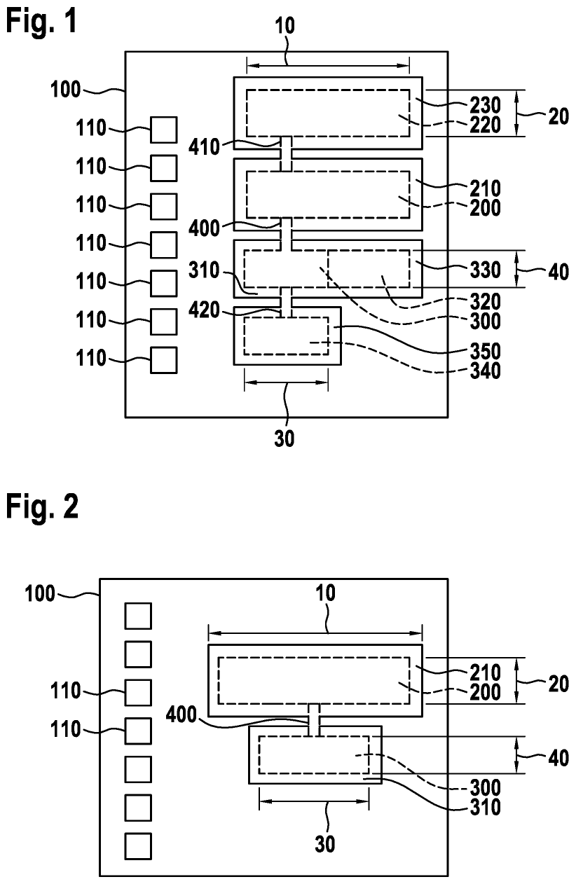

In a first embodiment according to FIG. 1, an arrangement is described in which two first membranes 200 and 220 of the first membrane type and two second membranes 300 and 340 of the second membrane type are arranged on a substrate 100 and/or on an additional layer system provided on the substrate. The membrane 200 has a membrane clamping region 210, the membrane 220 has a membrane clamping region 230, the membrane 300 has a membrane clamping region 310, and the membrane 340 has a membrane clamping region 350. The membrane clamping regions 210, 230, 310, and 350 are used to hold the corresponding membrane and to ensure that a membrane movement can occur independently of a membrane movement of the neighboring membrane. Furthermore, the design of the membrane clamping region can be used to define the geometric dimensions of a cavern located below the membrane into which the membrane can be deflected when pressure is applied. The cavern can be provided on the substrate 100 and/or can extend into the substrate 100. In the embodiment of FIG. 1, all membrane clamping regions 210, 230, 310 and 350 are structurally separated from one another by providing at least one separating structure or at least one wall between the membranes, the membrane clamping regions, and/or the caverns. In order to be able to achieve a larger total cavern volume based on the individual volumes of the caverns created, caverns can be connected to each other via at least one pressure equalization channel. The number, position, length, cross-sectional area, shape and/or location of the access into a cavern of the at least one pressure equalization channel can be chosen arbitrarily. In the present case, for example, the two caverns of the first membrane type are connected via a pressure equalization channel 410 and the two caverns of the second membrane type are connected via a further pressure equalization channel 420. In a further embodiment, the caverns of the first and second membrane types can optionally also be connected via an additional pressure equalization channel 400, whereby the connected total volume is increased again. Advantageously, by providing pressure equalization channels, temperature-related influences on a sensor signal and those dependent on a cavern volume and/or a cavern internal pressure in each case do not have to be ascertained and/or taken into account for each membrane and/or each membrane type. For contacting the detection means on or in the membranes, contacting elements 110 are provided on or in the substrate 100 and/or on or in the additional layer system provided on the substrate. These contacting elements 110 can be connected, via electrical conductor paths in or on the substrate 100 and/or layer system additionally provided in or on the substrate, to electrodes of a capacitive measured variable detection unit or a piezoresistive resistance detection unit.

The membranes 200 and 220 of the first membrane type have a width 10 and a length 20. In the present example of FIG. 1, the width 10 of the membranes 200 and 220 of the first membrane type is larger by a multiple, substantially twice as large, as the width 30 of the membranes 300 and 340 of the second membrane type. The length 40 of the membranes 300 and 340 of the second membrane type can correspond to the length 20 of the membranes 200 and 220 of the first membrane type. Alternatively, the lengths 20 and 40 of the membranes can also differ for the two membrane types, as shown in FIG. 1. Thus, it is possible to make not only the widths but also the lengths of the membranes 300 and 340 of the second membrane type longer than the lengths of the membranes 200 and 220 of the first membrane type by, in particular, a defined amount. Of course, it is also possible to vary only the widths or only the lengths and to leave the other side the same length. The latter approach has the advantage both that the pressure ranges can be coordinated more easily and the membranes of the two membrane types can be more easily arranged on the substrate 100 in an area-optimized manner.

In a further embodiment, the membranes of the first membrane type and the membranes of the second membrane type differ only in one of the lateral extensions on the substrate and/or on the additional layer system provided on the substrate. For this purpose, FIG. 1 shows a membrane 320 of the second membrane type with a membrane clamping region 330 which has the same width 10 as the membrane 200 of the first membrane type. The second side, i.e., the length 40 of this membrane 320, is shorter than the corresponding length 20 of the membrane 200 or the identically constructed membrane 220. By varying only one direction of the lateral membrane extension, a simpler scaling and thus a coordination of the pressure range of both membrane types can be achieved. The design of the pressure sensor according to this variation also has the advantage that the substrate surface can be utilized even better in terms of area utilization and no unused regions are created, or the sensor area can be minimized to the membrane areas used.

A further embodiment of the present invention consists in the fact that more membranes of one of the two membrane types are provided on the substrate than of the other membrane type. Thus, an embodiment of the pressure sensor can be provided in which, according to FIG. 1, the two membranes 200 and 220 of the first membrane type and only the membrane 300 or 320 of the second membrane type are provided on the substrate. Since a larger membrane surface usually allows a lower pressure to be detected more sensitively, this embodiment with the two larger membranes 200 and 220 of the first membrane type allows the pressure applied to the membranes to be determined more accurately in a lower first pressure range. This can be achieved by connecting the pressure detecting means of the membranes 200 and 220 (for example in the form of a Wheatstone bridge circuit) in parallel to achieve a higher measurement signal. Alternatively, the pressure values ascertained by the pressure detection means of the membranes 200 and 220 can be compared with each other and an error analysis can be carried out. In a further embodiment, an average value may be formed from both detected pressure variables of the membranes 200 and 220. Since the membrane surface of the membrane 300 or 320 is smaller, it bends less at lower pressures, which is why the pressure variable detected with this membrane is smaller in the lower first pressure range and is associated with a higher measurement deviation or a higher measurement error. If the pressure of the medium is above the first pressure range for which the first membrane type is designed/specified, the further detection of the pressure variables or pressure value detection is substantially carried out by the second membrane type. The use of at least two membrane types is particularly advantageous when measuring large pressure ranges, as high pressures and/or low pressures can be detected very precisely.

When using two membranes 200 and 220 of the first membrane type and two membranes 300 or 340 of the second membrane type, a special measurement value detection of the pressure variables can also be provided. During this measurement detection, the membranes 200 and/or 220 or the membranes 300 and/or 340 are each assigned to a half-bridge circuit or a full-bridge circuit of a Wheatstone bridge and the received bridge signals are further processed by circuitry.

Differently sized membranes 200, 220 and 300, 320 of the two membrane types can also be symmetrically arranged on the substrate 100 and/or on an additional layer system provided on the substrate, as shown in FIG. 2. Such a symmetrical arrangement is particularly useful in the case where the widths 10 and 30 and/or the lengths 20 and 40 of the membranes of the two membrane types are different. As in the embodiment according to FIG. 1, the caverns below the membranes 200 and 300 can be connected to at least one pressure equalization channel 400. The at least one pressure equalization channel 400 can be arranged centrally on one side of the corresponding cavern, as in FIG. 400. Alternatively, however, the at least one pressure equalization channel can also be arranged decentrally on one side of the cavern.

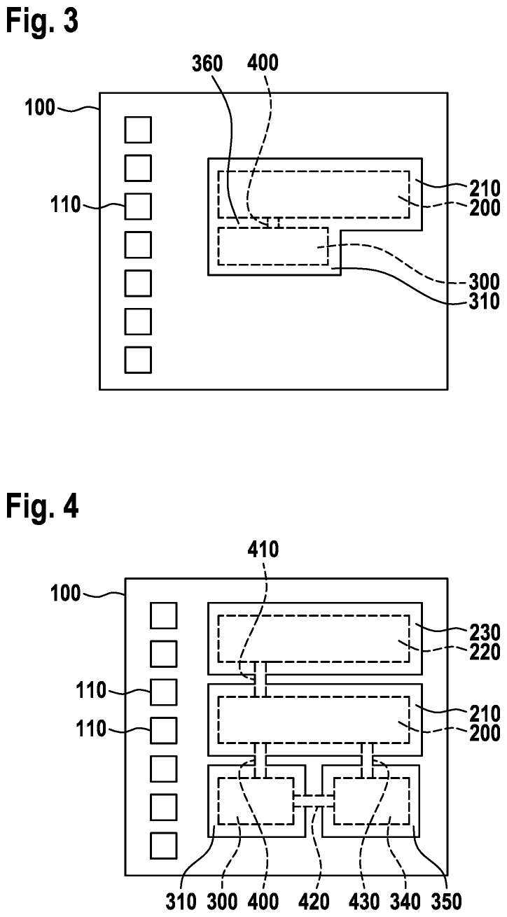

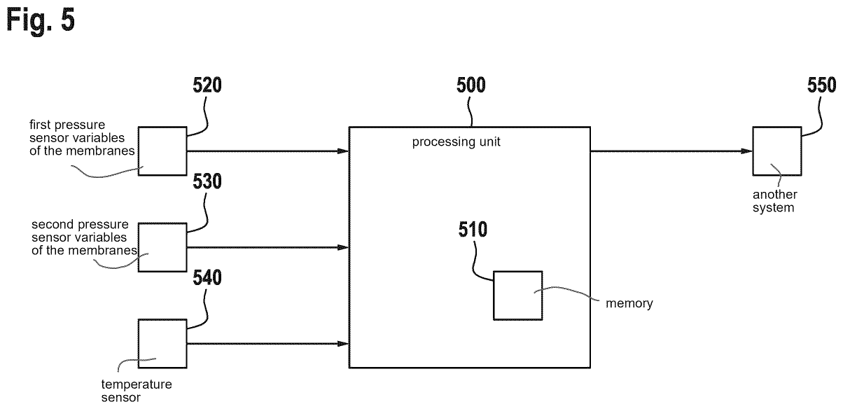

In FIGS. 1 and 2, it is clearly shown that the individual membranes 200, 220, 300, 320, and 340 each have their own separate membrane enclosure regions 210, 230, 310, 330, and 350. However, at least two of the membranes may also have at least partially a common membrane enclosure region 360 on one side. A possible embodiment of an at least partially shared membrane enclosure 360 along a width of a membrane 300 of the second membrane type and a partial region of a width of a membrane 200 of the first membrane type is shown in FIG. 3. Alternatively, a shared membrane enclosure region 360 of the membrane 300 can also be arranged centrally with respect to a membrane enclosure region of the membrane 200, as shown in FIG. 2. In a further embodiment, membranes can have a common membrane enclosure region along a width, wherein there is no flush alignment to one of the longitudinal sides. However, in the case of an at least partially shared membrane enclosure region 360, care must be taken to ensure that both membranes 200 and 300 can be deflected or moved independently of one another by the applied pressure, so that a membrane movement does not influence the adjacent membrane. The shared membrane enclosure region 360 can be supported by separating structures in the substrate or in the substrate surface and/or by separating structures in an additional layer system provided on the substrate. The separating structure can be in whole or in part the outer wall of one or both caverns under the membranes 200 and 300.

Another possibility for arranging different membranes of the first and second membrane type including the membrane enclosure regions in an area-optimized manner on/in a substrate surface and/or on/in an additional layer system provided on a substrate is shown in FIG. 4. As shown in the embodiment according to FIG. 1, it can be clearly seen that individual caverns can have at least one pressure equalization channel to one of the adjacent/neighboring caverns. In this case, for example, at least one pressure equalization channel 400, 430 can be provided from caverns under a plurality of membranes 300, 320, 340 of the second membrane type, in each case to a cavern at least under one membrane 200, 220 of the first membrane type. Optionally, at least one pressure equalization channel 420 can also be provided between the caverns under the membranes 300, 320, 340 of the second membrane type and/or at least one pressure equalization channel 410 between the caverns under the membranes 200, 220 of the first membrane type. Likewise, for example, in particular in the case of small caverns under membranes 300, 320, 340 of the second membrane type, pressure equalization channels 400, 430 and/or 420 can be aligned centrally to one side of the membrane, while at least one pressure equalization channel 410 can be arranged decentrally between larger caverns under membranes 200, 220 of the first membrane type.

In addition to the geometric choice of the lateral membrane dimensions due to the different variations in the width and length of the two membrane types, the pressure range to be measured by the layer structure and/or the layer thickness of the membranes and/or the membrane enclosures can also be determined in each case. Such a design makes it possible to advantageously coordinate measurements in different pressure ranges in order to be able to detect a large pressure range with a high degree of accuracy, for example. The elasticity of the membranes can also be advantageously influenced by varying the material composition and/or at least one layer thickness of the layer structure of the membranes. By influencing the elasticity of the membranes, the pressure-dependent deflections of the membranes can be influenced and each of the membrane types can be designed for defined pressure ranges. Alternatively or additionally, stiffening structures, which also influence the movement of the membrane, can be provided on, under, in, or next to a membrane. The upper limit of the pressure range for which the particular membrane type is intended can also be determined/specified by using stop structures below the membrane or on the cavern floor.

The detection of the pressure sensor variables of the individual detection means, which are assigned to the corresponding membranes of the first and second membrane type, can be carried out with a processing unit 500 or general evaluation unit. Here, first pressure sensor variables of the membranes 520 of the first membrane types are detected and/or read individually or as a total variable. Furthermore, second pressure sensor variables of the membranes 530 of the second membrane types are also detected and/or read individually or as a total variable. From the first and second pressure sensor variables thus detected, the processing unit 500 can derive a pressure value that represents the pressure of a liquid or gaseous medium applied to the membranes 520 and 530. For further processing, this pressure value can be forwarded to another system 550, which uses this pressure value for open-loop control, closed-loop control, and/or display. Alternatively, by interconnecting the measured value detection of the membranes of the two membrane types, a common pressure sensor variable can be detected from which the pressure value is determined.

The processing unit 500 can further comprise a memory 510 in which conversion factors, parameters, pressure sensor variables, pressure sensor values, and/or dependencies of the pressure sensor variables on other, in particular physical, (environmental) variables can be stored as a database. For example, it is possible that by means of at least one additional temperature sensor 540 the temperature of the applied liquid or gaseous medium, that of the pressure sensor structure, for example of the substrate and/or of the membrane, and/or the temperature of the environment of the pressure sensor are detected and taken into account when determining or deriving the pressure value from the detected pressure sensor variables.

1-11. (canceled)

12. A micromechanical pressure sensor, comprising:
at least two membranes, wherein:
at least one first membrane of the at least two membranes is a first membrane type and is provided above a first cavern in and/or on a substrate for detecting a first pressure sensor variable in a first pressure range,
at least one second membrane of the at least two membranes is a second membrane type and is provided above a second cavern in and/or on the substrate for detecting a second pressure sensor variable in a second pressure range, wherein the second pressure range differs partially from the first pressure range, and
lateral extensions of the first membrane and second membrane differ in at least one lateral direction, and
at least one pressure equalization channel is provided between the first cavern under the first membrane of the first membrane type and the second cavern under the second membrane of the second membrane type.

13. The micromechanical pressure sensor according to claim 12, wherein the lateral extensions of the first and second membranes differ in a lateral direction by a factor of 2:1,3:1, 4:1 or 3:2, 4:3, 5:4.

14. The micromechanical pressure sensor according to claim 12, wherein the first and second membranes of the first and second membrane types have a substantially rectangular shape.

15. The micromechanical pressure sensor according to claim 12, wherein n that each cavern of the first and second caverns has at least one pressure equalization channel of any shape, any length, and any cross-section, which at any position opens into an adjacent or further cavern.

16. The micromechanical pressure sensor according to claim 12, wherein each membrane of the first and second membranes has a membrane enclosure region using which an independent movement of the membrane is made possible, wherein at least two adjacent membranes have a common membrane enclosure region on one membrane side, at least in regions.

17. The micromechanical pressure sensor according to claim 12, wherein two membranes of the first membrane type and at least one membrane of the second membrane type are provided for detecting a pressure value, wherein a detection arrangement configured to detect pressure sensor variables of the first membrane type are electrically connected in such a way that they form a half-bridge arrangement or a full-bridge arrangement of a Wheatstone bridge configuration and a detection arrangement configured to detect pressure sensor variables of the second membrane type are arranged in a Wheatstone full-bridge, or half-bridge, or quarter-bridge configuration for detecting a pressure value.

18. The micromechanical pressure sensor according to claim 12, wherein. for detecting a pressure value, a multiple of membranes of the first membrane type is provided compared to membranes of the second membrane type, by a factor of 2:1 or 3:1 or 4:1.

19. The micromechanical pressure sensor according to claim 18, wherein the membranes of the first and second membrane types have a symmetrical arrangement among one another and/or to one another on the substrate.

20. The micromechanical pressure sensor according to claim 12, wherein lower pressures are detected using the first membrane of the first membrane type than with the second membrane of the second membrane type.

21. The micromechanical pressure sensor according to claim 12, wherein two membranes of at least one of the first and second membrane types are provided on the substrate, wherein at least one of the two membranes has stop elements on an underside of the membrane, wherein: (i) at least one of the membranes has no stop elements on an underside or (ii) at least two membranes have vertically and/or laterally differently formed stop elements.

22. A method for determining a pressure value with a micromechanical pressure sensor, wherein the micromechanical pressure sensor has at least two membranes, wherein:
at least one first membrane of the two membranes is a first membrane type and is provided above a first cavern in/on a substrate for detecting a first pressure sensor variable in a first pressure range,
at least one second membrane of the two membranes is a second membrane type and is provided above a second cavern in/on the substrate for detecting a second pressure sensor variable in a second pressure range, wherein the second pressure range differs at least partially from the first pressure range,
lateral extensions of the first and second membranes of the first and second membrane types differ in at least one lateral direction, and
at least one pressure equalization channel is provided between the first cavern under the first membrane of the first membrane type and the second cavern under the second membrane of the second membrane type;
the method comprising:
determining the pressure value based on the first and second pressure variables.
